(19) United States
(12) Patent Application Publication
(10) Pub. No.: US 2009/0011145 A1
(43) Pub. Date: Jan. 8, 2009

(54) Method of Manufacturing Vanadium Oxide Thin Film

(75) Inventors: Sun-Jin Yun, Daejeon-city (KR); Jung Wook Lim, Daejeon-city (KR); Hyun Tak Kim, Daejeon-city (KR); Byung Gyu Chae, Daejeon-city (KR); Bong Jun Kim, Daejeon-city (KR); Kwang Yong Kang, Daejeon-city (KR)

Correspondence Address: CANTOR COLBURN, LLP, 20 Church Street, 22nd Floor, Hartford, CT, 06103, US

(73) Assignee: Electronics and Telecommunications Research Instit ute, Daejeon-city (KR)

(21) Appl. No.: 12/064,807

(22) PCT Filed: Aug. 23, 2006
(86) PCT No.: PCT/KR2006/003307

§ 371 Date: Aug. 14, 2008

(30) Foreign Application Priority Data
Aug. 24, 2005 (KR) 10-2005-0077843
Dec. 3, 2005 (KR) 10-2005-0117265

(51) Int. Cl. C23C 16/513; C23C 16/00

(52) U.S. Cl. 427/569; 427/255.28

(57) ABSTRACT

Provided is a method of manufacturing a large-sized vanadium oxide thin film having a uniform surface, uniform film thickness and stable composition. According to the method, a vanadium-organometallic compound gas is injected into a chamber to form adsorption layer where molecules of the vanadium-organometallic compound are adsorbed on the surface of a substrate. After that, an oxygen precursor is injected into the chamber and thus allowed to accomplish surface-saturation reaction with the adsorbed materials to fabricate a vanadium oxide thin film.

### CROSS-REFERENCE TO RELATED PATENT APPLICATION

This application claims the benefit of Korean Patent Application No. 10-2005-0077843, filed on Aug. 24, 2005, and No. 10-2005-0117265, filed on Dec. 5, 2005, in the Korean Intellectual Property Office, the disclosures of which are incorporated herein in their entirety by reference.

### BACKGROUND OF THE INVENTION

1. Field of the Invention

The present invention relates to a method of manufacturing a vanadium oxide thin film, and more particularly, to a method of manufacturing a vanadium oxide thin film using atomic layer deposition (ALD) and plasma-enhanced ALD (PEALD).

2. Description of the Related Art

Vanadium oxides such as V₂O₃ and VO₂, among V₂O₃, VO₂, and V₂O₅ are materials that have an abrupt transition from an insulator to a metal state (metal-insulator transition, MIT), when the temperature, electric field, or pressure increases within a controllable condition. Particularly, since the resistance of VO₂ changes abruptly at a temperature around 340K, which is higher than the room temperature, VO₂ may be effectively used for electronic devices such as switches and transistors.

The metal-insulator transition of a thick vanadium oxide film or bulk vanadium oxide at a temperature is generally known, but it is not easy to fabricate a thin vanadium oxide film revealing abrupt MIT. Therefore, there are limitations in using the vanadium oxide films for devices such as switches and transistors. Methods of manufacturing a thin vanadium oxide thin film include sputter deposition, pulsed laser deposition (PLD), and a sol-gel method. The best vanadium oxide thin film could be formed using PLD.

In the PLD method, however, deposition is restricted only to a small area so that the film uniformity is very poor, and protuberances are formed on the surface of a thin film. Accordingly, the PLD is adequate only for studying the physical properties of the vanadium oxide thin film, but is not proper for forming a thin film for use in a practical device that requires a large area thin film having a uniform and smooth surface and a uniform thickness distribution. Also, a vanadium oxide thin film manufactured using PLD changes its property depending, particularly, on the amount of oxygen, which is very difficult to control.

The sol-gel method requires one or two additional heat treatments of a thin film in an oxidation or a reduction atmosphere in addition to the heat treatment to eliminate solvent from the sol state of the film coated with precursor solution or vanadium oxide powder in its liquid state dispersed in water. Furthermore, it has been reported that the vanadium oxide thin-film such as a VO₂ thin film manufactured using the sol-gel method does not show satisfactory physical properties when applied to a thin film for a practical device.

Vanadium oxide thin films may often simultaneously exist in many different phases such as V₂O₃, VO₂, V₂O₅, and V₃O₇, and they can change into a different phase. Generally, to obtain a VO₂ thin film having a relatively high quality, a method of forming a V₂O₅ thin film first and then annealing the V₂O₅ thin film in a reduction atmosphere is widely used. That is, the method includes a process of forming a single phase or mixed phase vanadium oxide film from a precursor, and additional heat treatment of the film may be also required to form a single phase. The heat treatment is divided into oxidation heat treatment to completely make the single phase or mixed phase vanadium oxide film into a V₂O₅ thin film, and reduction heat treatment to form the VO₂ thin film in a reduction atmosphere. However, in this case, the process of forming the VO₂ thin film is complicated.

Furthermore, it is also difficult to manufacture a uniform V₂O₅ thin film. For example, when the V₂O₅ thin film is manufactured using a sputter deposition, it is difficult to manufacture a uniform single phase V₂O₅ thin film because its composition can change due to the partial pressure of an oxygen gas in the process chamber.

Also, U.S. Pat. No. 6,156,395 discloses a method of depositing a vanadium oxide thin film used for a cathode of a lithium ion battery using plasma-enhanced chemical vapor deposition (PECVD) utilizing hydrogen and oxygen gases. However, even in this case, various phase vanadium thin films are formed and the kinds of formed phase depend on the oxygen partial pressure in the chamber. Also, unlike the ALD, which is controlled using surface saturation adsorption and surface saturation reaction in principle, a thin film obtained using the PECVD has unstable composition and non-uniformity.

### SUMMARY OF THE INVENTION

The present invention provides a method of manufacturing a large area vanadium oxide thin film having uniform thickness and stable composition.

According to an aspect of the present invention, there is provided a method of manufacturing a vanadium oxide thin film, the method including: loading a substrate in a chamber; (1) injecting vapor of a vanadium-organometallic compound precursor into the chamber to uniformly form an adsorption layer containing vanadium precursor on the substrate by surface saturation adsorption; (2) injecting an inert gas into the chamber in order to purge residual vanadium-organometallic compound molecules that has not been adsorbed; (3) injecting an oxygen precursor (oxidant) into the chamber to allow the oxygen precursor to accomplish surface-saturation reaction with the adsorbed vanadium precursors to form a vanadium oxide layer in case of ALD; and (4) injecting an inert gas into the chamber in order to purge out the side product of the surface reaction and residual oxidant particles. By repeating the steps (1)-(4) several ten or several hundred times, a vanadium oxide thin film of a certain thickness is formed. In step (3), an oxygen plasma can be generated for a predetermined period of time to allow the reactive species in oxygen plasma to accomplish surface-saturation reaction with the adsorbed vanadium precursors to form a vanadium oxide layer, in case of PEALD. The pressure of reaction chamber is in the range of 0.5 to 10 torr and the content of oxidant gas in the reaction environment is in the range of 2 to 20%.

The substrate may be a sapphire substrate whose crystal lattice constant is similar to that of the vanadium oxide layer and thus vanadium oxide film deposited on sapphire substrates has good crystalline quality. However, since the small sapphire substrate has low productivity and high cost, thereby increasing the cost of the method, the substrate may be formed of at least one selected from the group consisting of Si, glass, quartz, and SiO₂-deposited Si. The diameter of the substrate may be 5 inch, 8 inch or larger.

A valence of the vanadium ion contained in the vanadium-organometallic compound precursors may be one of +3, +4, and +5. The vanadium-organometallic compound containing vanadium whose valence is +4 may be one selected from the group consisting of V(NEt₂)₄, V{N(EtMe)}₄, and V(NMe₂)₄. Here, Me is methyl group (—CH₃) and Et is ethyl group (—C₂H₅). Also, the vanadium-organometallic compound precursor may be one selected from the group consisting of VX₄, where X=Cl, F, Br, or I, vanadium 2,4-pentadionate, vanadium acetone acetonate, and cyclopentadienyl vanadium tetracarbonyl.

The vanadium-organometallic compound precursor containing vanadium whose valence is +5 may be one selected from the group consisting of VO{N(EtMe)}₃, VO(NMe₂)₃, VO(OMe)₃, VO(OEt)₃, VO(OC₃H₇)₃, and VOX₃, where X=Cl, F, Br, or I. Also, the vanadium-organometallic compound gas may be one selected from the group consisting of VX₃, where X=Cl, F, Br, or I.

A temperature of the vanadium precursor may be maintained such that a vapor pressure of the vanadium-organometallic precursor is in a range of 0.01-10 torr, and the temperature of the reaction chamber may be 350° C. or lower.

The oxygen precursor, i.e. the oxidant, may be one selected from the group consisting of ozone, H₂O, oxygen, and oxygen plasma.

The method may further include, after the deposition of vanadium oxide film by the method of present invention, in-situ annealing of the vanadium oxide film or doped vanadium oxide film. The heat treatment may be performed in the deposition chamber, or an adjacent chamber having a similar atmosphere to that of the deposition chamber.

The method may further include the step of oxygen plasma generation to form the vanadium oxide thin film for a predetermined period of time during the step (4), that is, the oxidation step of vanadium precursor on the surface during atomic layer deposition of vanadium oxide. The time for which the plasma phase is maintained may be equal to or shorter than a time for which the oxygen is injected.

According to another aspect of the present invention, there is provided a method of manufacturing a vanadium oxide thin film, the method including: loading a substrate in a chamber; (1) injecting a (V{N(C₂H₅CH₃)}₄) (tetra(ethylmethylamino) vanadium, TEMAV) vapor into the chamber to form adsorption layer containing vanadium precursor on the surface of the substrate by surface saturation adsorption; (2) injecting an inert gas into the chamber in order to purge residual TEMAV molecules that has not been adsorbed; (3) injecting H₂O into the chamber to allow the H₂O to accomplish surface-saturation reaction with the adsorbed vanadium precursors to form a vanadium oxide layer; and (4) injecting an inert gas into the chamber in order to purge out by-products or residual oxidants. By repeating the steps (1)-(4) several ten or several hundred times, a vanadium oxide thin film of a certain thickness is formed.

According to another aspect of the present invention, there is provided a method of manufacturing a vanadium oxide thin film, the method including: loading a substrate in a chamber; (1) injecting a TEMAV gas into the chamber to form adsorption layer containing vanadium precursor on the surface of substrate by surface saturation adsorption; (2) injecting an inert gas into the chamber in order to purge residual TEMAV molecules that has not been adsorbed; (3) injecting O₂ gas into the chamber and generating an oxygen plasma for a predetermined period of time to allow the reactive species in oxygen plasma to accomplish surface-saturation reaction with the adsorbed vanadium precursors to form a vanadium oxide layer; and (4) injecting an inert gas into the chamber in order to purge out by-products or residual oxidants. By repeating the steps (1)-(4) several ten or several hundred times, a vanadium oxide thin film of a certain thickness is formed.

### BRIEF DESCRIPTION OF THE DRAWINGS

The above and other features and advantages of the present invention will become more apparent by describing in detail exemplary embodiments thereof with reference to the attached drawings in which:

FIG. 1 is a timing diagram for explaining an ALD method of manufacturing a vanadium oxide thin film according to a first embodiment of the present invention;

FIG. 2 is a timing diagram for explaining a plasma-enhanced ALD method of manufacturing a vanadium oxide thin film according to a second embodiment of the present invention;

FIG. 3 is a cross-sectional view of a device having a vanadium oxide thin film manufactured according to the embodiment of the present invention;

FIG. 4 is a cross-sectional view of a device having a vanadium oxide thin film manufactured on a buffer layer-deposited substrate according to the embodiment of the present invention;

FIG. 5 is a graph illustrating a deposition rate of a vanadium oxide thin film versus temperature by using TEMAV and O₂ plasma as precursors;

FIG. 6 is a graph illustrating the composition of a vanadium oxide thin film fabricated using TEMAV and O₂ plasma as precursors at a temperature 150° C., obtained using Auger electron spectroscopy (AES); and

FIG. 7 is a graph illustrating a resistance change of a vanadium oxide thin film annealed in the reaction chamber versus temperature.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements.

Unlike a general chemical vapor deposition (CVD), a method of manufacturing a vanadium oxide thin film according to embodiments of the present invention uses surface saturation reaction. In the embodiments of the present invention, H₂O or an oxygen plasma is used as an oxidant.

### First Embodiment

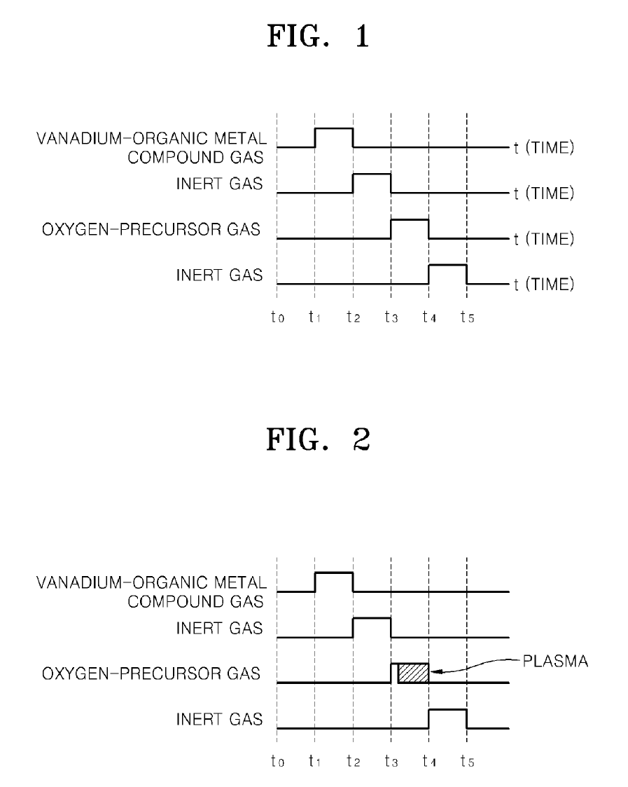

FIG. 1 is a timing diagram for explaining an ALD method of manufacturing a vanadium oxide thin film according to a first embodiment of the present invention.

Referring to FIG. 1, a substrate is loaded in a chamber (t₀-t₁). After that, a vanadium-organometallic compound, which is a precursor of vanadium, is injected into the chamber so that an adsorption layer of vanadium precursor molecules are formed on the surface of the substrate by surface saturation adsorption (t₁-t₂). Here, the surface saturation adsorption means that adsorption does not occur any more after the vanadium precursor molecules are all adsorbed in a monolayer on the surface of the substrate even when excess amount of precursor molecules is injected. An inert gas, e.g., a nitrogen or argon (Ar) gas is injected into the chamber in order to purge out a vanadium-organometallic compound gas that remains in the chamber and is not adsorbed (t₂-t₃). An oxygen precursor (oxidant) is injected into the chamber to allow the oxygen precursor to accomplish surface-saturation reaction with the adsorbed materials to form a monolayered vanadium oxide thin film (t₃-t₄). Here, the surface saturation reaction means the oxidant react with the adsorbed materials containing vanadium on the surface, and the reaction occurs only on the surface even when excess amount of oxidant is injected. Subsequently, an inert gas is injected into the chamber in order to purge out by-products remaining in the chamber (t₄-t₅). By repeating the steps of t₁-t₅ several ten or several hundred times, a vanadium oxide thin film of a certain thickness is formed.

A valence of the vanadium ion of the vanadium-organometallic compound, which is a precursor of a vanadium oxide, may be one of +3, +4, and +5. For example, the vanadium-organometallic compound containing the vanadium ion whose valence is +4 may be at least one selected from the group consisting of V(NEt₂)₄, V{N(EtMe)}₄, and V(NMe₂)₄. The vanadium-organometallic compound containing the vanadium whose valence is +5 may be at least one selected from the group consisting of VO{N(EtMe)}₃, VO(NMe₂)₃, VO(OMe)₃, VO(OEt)₃, VO(OC₃H₇)₃, and VOX₃, where X=Cl, F, Br, or I. Also, the vanadium-organometallic compound may be at least one selected from the group consisting of VX₃, where X=Cl, F, Br, or I, VX₄, where X=Cl, F, Br, or I, vanadium 2,4-pentadionate, vanadium acetone acetonate, and cyclopentadienyl vanadium tetracarbonyl. The oxygen precursor may be an oxidant such as H₂O and oxygen.

The temperature of a source supply system in the deposition apparatus should be maintained such that a vapor pressure of the vanadium-organometallic compound is 0.01-10 torr, and the amount of the vanadium-organometallic compound required for reaction is appropriately controlled according to an injection time (t₁-t₂) by the vapor pressure. The temperature of the reaction chamber should be higher than that of the source supply system and the temperature of the reaction chamber may be 500° C. or lower. The temperature of reaction chamber depends on the kind of vanadium precursors used in the deposition process of vanadium oxide. The pressure of reaction chamber is in the range of 0.5 to 10 torr and the content of oxidant gas in the reaction environment is in the range of 2 to 20%.

The ALD method utilizing the surface saturation adsorption and reaction is greatly different from the CVD method. In the ALD method, deposition is performed in units of atomic layer and the deposition rate is less than or equal to an atomic layer. Therefore, a uniform thin film can be obtained even though the surface of a substrate is very rough or the aspect ratio of a structure formed on the substrate is very high. When the ALD method is used, a constant deposition rate is maintained by the surface saturation phenomenon even though an excessive amount of precursors is supplied. On the other hand, in the conventional deposition method including PECVD method, V₂O₅ thin film, that is the most stable oxide among vanadium oxides, is obtained and the V₂O₅ thin film should be heat-treated in reduction environment to manufacture a VO₂ thin film. However, in the first embodiment of the present invention a VO₂ thin film having stoichiometric composition can be directly formed.

### Second Embodiment

FIG. 2 is a timing diagram for explaining a PEALD method according to a second embodiment of the present invention. The second embodiment is the same as the first embodiment except that the oxygen plasma, which is an oxygen precursor, is utilized.

Referring to FIG. 2, the oxygen plasma is generated during the injection of oxygen step (t₃-t₄). The oxygen plasma may be maintained for the same time as or shorter than the injection time, t₃-t₄, of the oxygen precursor. In detail, the plasma may be generated simultaneously with the injection of the oxygen into the chamber, or may be generated when a predetermined period of time elapses during the injection of oxygen. The plasma may be generated directly within a reaction chamber, or may be formed through a remote manner in which reactive particles are generated in an adjacent plasma chamber and injected into a reaction chamber.

In the PEALD method according to the second embodiment of the present invention, deposition is performed in units of atomic layer and the deposition rate is less than or equal to an atomic layer. Therefore, a uniform thin film can be obtained even though the surface of a substrate is very rough or the aspect ratio of a structure formed on the substrate is very high. When the ALD method is used, a constant deposition rate is maintained by the surface saturation phenomenon even though an excessive amount of precursors is supplied. On the other hand, in the conventional deposition method including PECVD method, V₂O₅ thin film, that is the most stable oxide among vanadium oxides, is obtained and the V₂O₅ thin film should be heat-treated in reduction environment to form a VO₂ thin film. However, in the first embodiment of the present invention a VO₂ thin film having stoichiometric composition can be directly formed. Also, in the second embodiment, the VO₂ thin film may be formed even at a low reaction temperature compared to the first embodiment. Furthermore, when the plasma phase is sufficiently maintained, the crystallinity of the vanadium oxide film may be improved even more.

The temperature of the reaction chamber should be higher than that of the source supply system and the temperature of the reaction chamber may be 500° C. or lower. The temperature of reaction chamber depends on the kind of vanadium precursors used in the deposition process of vanadium oxide. The pressure of reaction chamber is in the range of 0.5 to 10 torr and the content of oxidant gas in the reaction environment is in the range of 2 to 20%.

### EXPERIMENTAL EXAMPLES

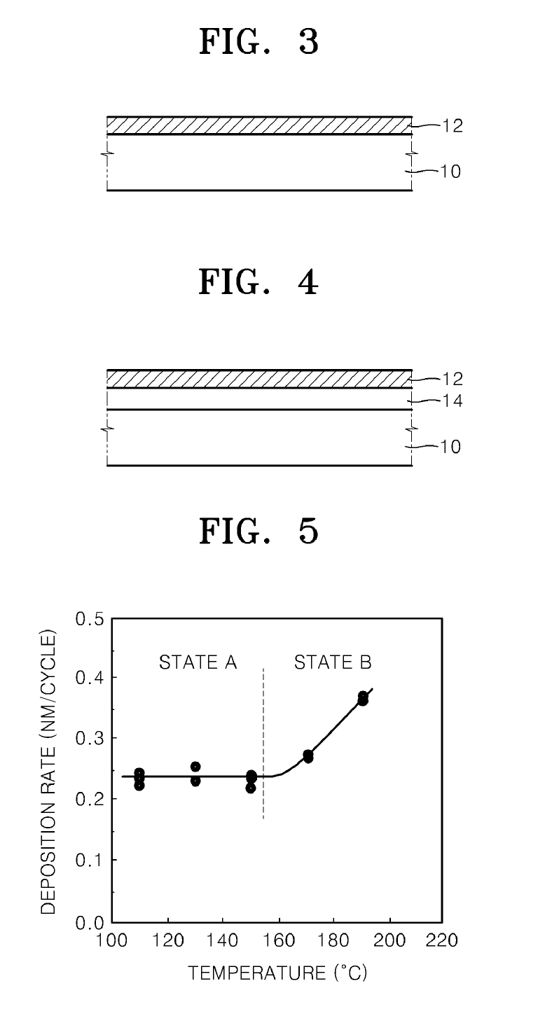

A device containing the vanadium oxide thin film (referred to as a vanadium oxide film 12 hereinafter) described in the second embodiment is manufactured as explained with reference to FIGS. 3 and 4. FIG. 4 illustrates a buffer layer 14 that is further formed in the device illustrated in FIG. 3, if necessary.

To manufacture the vanadium oxide film 12, a silicon substrate 10 with a diameter of 2-12 inch is loaded to the reaction chamber first. After that, (1) tetraethylmethylamino vanadium (V{N(C₂H₅CH₃)}₄) (TEMAV) vapor is injected into a chamber to adsorb to form a saturated adsorption layer on the Si surface 10, and (2) an inert gas is injected into the chamber to purge out a gas remaining therein. Next, (3) an oxygen gas is injected into the chamber and oxygen plasma is generated, then the energetic particles of oxygen plasma react with the adsorbed vanadium precursors to form a monolayered vanadium oxide film 12. After that, (4) an inert gas is injected into the chamber to purge out a remaining by-product of the surface reaction. The above-described processes (1)-(4) are repeated several ten to several thousand times to manufacture a vanadium oxide film. When the above-describe processes (1)-(4) was repeated 1,100 times, VO₂ film of a thickness of 300 nm was fabricated at the deposition temperature of 150° C. Also, for the buffer layer 14, a TiO₂ or Al₂O₃ is formed at a thickness of 100 nm.

After purging the by-product of reaction, the vanadium oxide film 12 may be in-situ heated. At this point, the heat treatment is intended for eliminating defects from the formed vanadium oxide film 12, not for changing the phase of the vanadium oxide. The heat treatment may be performed in the chamber or an adjacent chamber having a similar atmosphere to that of the deposition chamber.

A sapphire single crystal substrate is generally used to form a vanadium oxide film having a metal-insulator transition property because the sapphire single crystal has a lattice constant similar to that of the vanadium oxide film and so a vanadium oxide film having excellent crystallinity may be grown. However, the sapphire substrate is expensive and difficult to be manufactured in a large diameter. Accordingly, the present invention uses a silicon substrate of a large diameter, e.g., 5 to 12 inch substrate. A glass or quartz substrate having a diameter of 5 to 12 inch, which is also easy to be manufactured, may also be used.

A crystalline thin film having a lattice constant similar to that of the vanadium oxide film may be used for a buffer layer 14 in order to improve the crystallinity of the vanadium oxide film. For example, the buffer layer 14 may be at least one selected from the group consisting of an aluminum oxide layer, a high dielectric layer, and a crystalline metal layer, and a silicon oxide layer. At this point, the aluminum oxide layer maintaining some degree of crystallinity suffices for this purpose, and the silicon oxide layer may be formed as thin as possible. Particularly, a high dielectric layer having an excellent crystallinity, such as a TiO₂ layer, MgO layer, a ZrO₂ layer, a Ta₂O₅ layer, and a HfO₂ layer, or a mixed layer of these, and/or a multi-layer including a crystalline metal layer may be formed as the buffer layer 14. When the plasma phase is sufficiently maintained above the vanadium oxide film 12 on the buffer layer 14, the crystallinity of the vanadium film 12 may be improved even more.

FIG. 5 is a graph illustrating a deposition rate of a vanadium oxide film versus temperature. Referring to FIG. 5, the vanadium oxide film is deposited at a constant rate in a temperature range (state A) of 100-170° C., where the deposition rate does not vary with the temperature. This means that the vanadium oxide film is formed by a surface saturation reaction between TEMAV adsorbed on the surface and oxidant.

On the other hand, the deposition rate increases with the temperature in a temperature region (state B) above about 170° C. The increase of the deposition rate with the temperature means that the vanadium oxide film is deposited using CVD when the vanadium precursor is TEMAV and the deposition temperature is higher than 170° C. In detail, the precursor of the vanadium, TEMAV, is decomposed at a temperature higher than 170° C. and the gas phase reaction between the decomposed precursors is performed, so that chemical vapor deposition occurs by reaction in a gas phase, not by the surface saturation reaction. Accordingly, the deposition rate increases with increasing the temperature. When the vanadium oxide layer is deposited using the CVD, the thickness of the formed thin film becomes non-uniform and the composition of the thin film becomes unstable.

The temperature at which CVD occurs instead of ALD depends on the precursor of the vanadium oxide. For example, when VO(OC₃H₇)₃ is used as the precursor, the temperature is about 200° C. When VOCl₃ is used as the precursor, the temperature is about 300° C. Also, when tri-halogenide vanadium or tetra-halogenide vanadium is used as the precursor, a higher temperature, e.g., 350-500° C. are required, which therefore makes it possible to increase the temperature up to 500° C. Accordingly, the temperature at which the vanadium oxide film 12 is formed using ALD may be in a range of 100-500° C., depending on the precursor of the vanadium oxide.

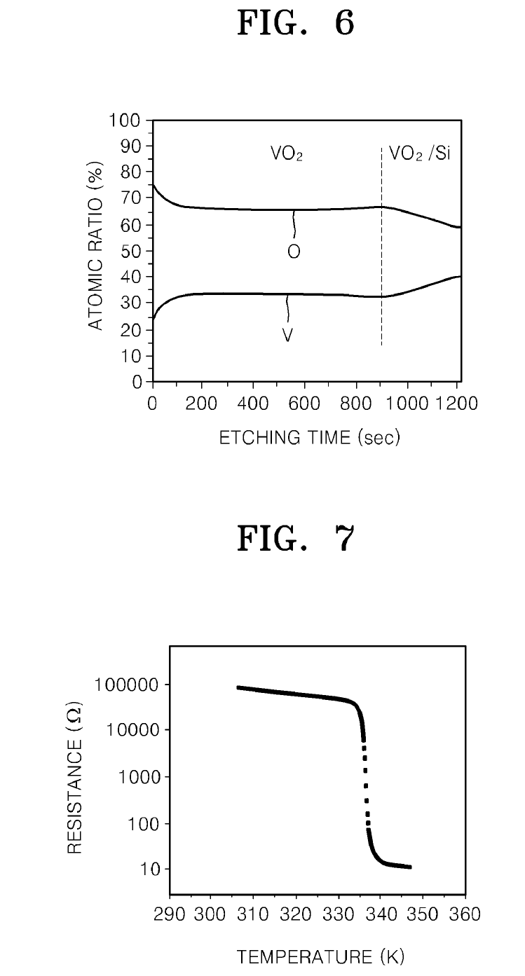

FIG. 6 is a graph illustrating the composition of a vanadium oxide film manufactured by using TEMAV as vanadium precursor at a temperature 150° C., analyzed using Auger electron spectroscopy (AES). Here, an etching time is a time for which a vanadium oxide film for AES depth profiling is etched. When the etching time elapses about 900 seconds, a boundary region (VO₂/Si) of a Si substrate between the vanadium oxide film and the Si substrate appears. As illustrated in FIG. 6, a composition ratio of vanadium to oxygen is about 1:2, which shows that the vanadium that has a valence +4 combines with oxygen that has a valence −2 to constitute VO₂. That is, the VO₂ thin film is chemically stable.

FIG. 7 is a graph illustrating a resistance change of the vanadium oxide film of FIG. 5 versus temperature. Referring to FIG. 7, the vanadium oxide film is deposited using PEALD, and after undergoing a predetermined heat treating in the reaction chamber, it shows an abrupt metal-insulator transition around 65° C. (335K). That is, resistance of the vanadium oxide (VO₂) film abruptly reduces from about 50,000Ω to about 10Ω. The vanadium oxide film according to the present invention has a resistance variation of about 50,000Ω, namely, it has high electrical conductivity at a temperature higher than 65° C.

In the method of manufacturing a vanadium oxide thin film according to the present invention, a vanadium oxide film, is directly formed on a substrate of a large diameter using ALD or PEALD.

Since a surface saturation reaction is used in ALD and PEALD, the vanadium oxide film has stable composition and uniform surface structure and film thickness.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a vanadium oxide thin film, the method comprising:
loading a substrate in a chamber;
(1) injecting a vanadium-organometallic compound vapor into the chamber to uniformly form adsorption layer of vanadium precursors on the substrate using surface saturation absorption;
(2) injecting an inert gas into the chamber in order to purge a vanadium-organometallic compound gas that has not been adsorbed; and
(3) injecting an oxygen precursor into the chamber to allow the oxygen precursor to accomplish surface-saturation reaction with the adsorbed materials to form a vanadium oxide thin film; and
(4) injecting an inert gas into the chamber in order to purge by-products of surface reaction in step (3) and residual oxidants; and
5) repeating the above-described processes (1)-(4) until vanadium oxide film of desired thickness is obtained.

2. The method of claim 1, wherein the substrate is formed of at least one selected from the group consisting of Si, glass, quartz and SiO₂-coated Si.

3. The method of claim 1, wherein the substrate has a diameter of 2-12 inch.

4. The method of claim 1, wherein a valence of the vanadium ion contained in the vanadium-organometallic compound precursors is one of +3, +4, and +5.

5. The method of claim 4, wherein the vanadium-organometallic compound gas containing the vanadium whose valence is +4 is one selected from the group consisting of V(NEt₂)₄, V{N(EtMe)}₄, and V(NMe₂)₄, where Me is ═CH₃ and Et is ═C₂H₅.

6. The method of claim 4, wherein the vanadium-organometallic compound gas containing the vanadium whose valence is +5 is one selected from the group consisting of VO{N(EtMe)}₃, VO(NMe₂)₃, VO(OMe)₃, VO(OEt)₃, VO(OC₃H₇)₃, and VOX₃, where X=Cl, F, Br, or I, and Me is CH₃ and Et is C₂H₅.

7. The method of claim 1, wherein the vanadium-organometallic compound gas is one selected from the group consisting of VX₃, where X==Cl, F, Br, or I, VX₄, where X=Cl, F, Br, or I, vanadium hexacarbonyl, vanadium 2,4-pentadionate, vanadium acetone acetonate, and cyclopentadienyl vanadium tetracarbonyl.

8. The method of claim 1, wherein a temperature of the reaction is maintained such that a vapor pressure of the vanadium-organometallic compound vapor is in a range of 0.01-10 torr.

9. The method of claim 1, wherein a temperature of the reaction is in a range of 100-350° C.

10. The method of claim 1, wherein a temperature of the reaction is in a range of 350-500° C.

11. The method of claim 10, wherein the vanadium-organometallic compound gas is vanadium halogenide.

12. The method of claim 1, wherein the oxygen precursor is one selected from the group consisting of ozone, H₂O, and an oxygen plasma.

13. The method of claim 1, further comprising, before the injecting of the vanadium-organometallic compound vapor, forming a buffer layer having a lattice constant similar to that of the vanadium oxide compound gas on the substrate.

14. The method of claim 13, wherein the buffer layer is at least one selected from the group consisting of an aluminum oxide layer, a silicon oxide layer, an MgO layer, an insulation layer having a high dielectric constant, and a crystalline metal layer.

15. The method of claim 1, further comprising, after forming vanadium oxide film of desired thickness, in situ heat-treatment of the vanadium oxide thin film.

16. The method of claim 15, wherein the heat treating is performed in the chamber, or in an adjacent chamber having a similar atmosphere to that of the chamber, and the atmosphere in the adjacent chamber is a vacuum atmosphere or an inert gas atmosphere.

17. The method of claim 1, wherein the oxidant is oxygen plasma and the plasma is maintained for a predetermined period of time in the PEALD cycles.

18. The method of claim 17, wherein the time for which the plasma is maintained is the same as or shorter than a time for which the oxygen precursor is injected in the PEALD cycles.

19. The method of claim 17, wherein the plasma is directly applied to the surface of the substrate within the chamber or reactive particles generated due to a plasma in an adjacent chamber are injected to the chamber.

20. A method of manufacturing a vanadium oxide thin film, the method comprising:
loading a substrate in a chamber;
(1) injecting a TEMAV (tetra ethyl methyl amino vanadium: V{N(C₂H₅CH₃)}₄) vapor into the chamber to form an adsorption layer containing vanadium ion on the surface by surface saturation adsorption;
(2) injecting an inert gas into the chamber in order to purge a TEMAV vapor that has not been adsorbed;
(3) injecting H₂O into the chamber to allow the H₂O to accomplish surface-saturation reaction with the adsorbed materials to form a vanadium oxide thin film; and
(4) injecting an inert gas into the chamber in order to purge a reaction by-product remaining in the chamber,
wherein the steps (1)-(4) are repeated a predetermined number of times.

21. The method of claim 20, wherein the substrate has a diameter of 2-12 inch.

22. The method of claim 20, wherein a temperature of the reaction under which the TEMAV gas is adsorbed on the substrate and the thin film is formed by the surface saturation reaction is in a range of 100-170° C.

23. The method of claim 20, further comprising, before the injection of the TEMAV gas, forming a buffer layer having a lattice constant similar to that of the vanadium oxide compound gas on the substrate.

24. The method of claim 20, further comprising, after forming vanadium oxide film, of desired thickness, in situ heat-treatment of the vanadium oxide thin film.

25. A method of manufacturing a vanadium oxide thin film, the method comprising:
loading a substrate in a chamber;
(1) injecting a TEMAV (tetra ethyl methyl amino vanadium: V{N(C₂H₅CH₃)}₄) vapor in the chamber to form adsorption layer containing vanadium ion on the surface of the substrate by surface saturation adsorption;
(2) injecting an inert gas into the chamber in order to purge a TEMAV vapor that has not been absorbed;
(3) injecting the oxygen gas into the chamber and generating an oxygen plasma for a predetermined period of time to allow the energetic particles in oxygen plasma to accomplish surface-saturation reaction with the adsorbed materials to form a vanadium oxide thin film; and
(4) injecting an inert gas to the chamber in order to purge a reaction by-product remaining in the chamber,
wherein the steps (1)-(4) are repeated a predetermined number of times.

26. The method of claim 25, wherein the substrate has a diameter of 2-12 inch.

27. The method of claim 25, wherein a temperature of the reaction under which the TEMAV vapor is adsorbed on the substrate and the thin film is formed by the surface saturation reaction is in a range of 100-1700° C.

28. The method of claim 25, wherein the time for which the plasma is maintained is the same as or shorter than a time for which the oxygen gas is injected.

29. The method of claim 25, wherein the plasma is directly applied to the surface of the substrate within the chamber or reactive particles generated due to a plasma in an adjacent chamber are injected to the chamber.

30. The method of claim 25, further comprising, before the injection of the TEMAV gas, forming a buffer layer having a lattice constant similar to that of the vanadium oxide compound gas on the substrate.

31. The method of claim 2.5, further comprising, after forming vanadium oxide film of desired thickness, in situ heat-treatment of the vanadium oxide thin film.
